(19) United States
(12) Patent Application Publication
(10) Pub. No.: US 2004/0011555 A1
(43) Pub. Date: Jan. 22, 2004

(54) Method for manufacturing printed circuit board with stacked wires and printed circuit board manufacturing according to the mehtod

(76) Inventor: Tsung Chin Chiu, Taipei (TW)

Correspondence Address: Tsung Chin Chiu, 235 Chung - Ho, Box 8-24, Taipei, TW

(21) Appl. No.: 10/199,835

(22) Filed: Jul. 22, 2002

(51) Int. Cl. H05K 1/03

(52) U.S. Cl. 174/256

(57) ABSTRACT

A method for manufacturing a printed circuit board with stacked wires and a printed circuit board made by the method are disclosed. In the printed circuit board, each wire layers being formed by pretreatment, coating or laminating photoimageable resist, exposing, developing, etching wires on a substrate; coating an insulating layer on the circuit board; removing the insulating layer upon the wires so as to expose the wires; and then performing PTH process and plating copper for forming another wires. Thereby, line thickness of the printed circuit board is increased and the wires are stacked continuously.

### FIELD OF THE INVENTION

The present invention relates to wires on a printed circuit board (PCB), and particularly to a method for manufacturing a printed circuit board and a printed circuit board manufacturing according to the method. In that, the wires are stacked so as to have a desired width and a desired height to width ratio.

### BACKGROUND OF THE INVENTION

Due to confinement of the manufacturing process of a printed circuit board (PCB), in general, the T/W (thickness/width) ratio of wires on a printed circuit board is below 1. Since the H/W ratio of the wire can not be increased and thus the width of the wire can not be reduced. And therefore, the product having the printed circuit board can not be made with a smaller size. This is because that for same conductor thickness if the width of a wire is reduced, the conductor area of the wire will be reduced so that the carrying current in the wire will be reduced. As a result, conductor width will be confined unless they can increase conductor thickness.

### SUMMARY OF THE INVENTION

Accordingly, the primary object of the present invention is to provide a method for manufacturing a printed circuit board having stacked wires and a printed circuit board manufacturing by the method. Thereby, the thickness of wires on the printed circuit board can be increased and wires can be stacked on the printed circuit board for getting enough conducting area.

To achieve above objects, the present invention provides a method for manufacturing a printed circuit board comprising the steps of: forming wires on a substrate by pretreatment, coating or laminating photoimageable resist; exposing, developing, etching; coating with an insulating layer on the circuit board; removing the insulating layer upon the wires so as to expose the wires; performing PTH process and plating copper for forming another wires; repeated above process. Thereby, stacked wires being formed; if the thickness is enough the printed circuit board is drilled and then the conventional PCB process is performed to make a finished good PCB.

Furthermore, the present invention provide a printed circuit board with stacking wires comprising a plurality of wire layers. Each wire layer being formed by pretreatment, coating or laminating photoimageable resist; exposing, developing, etching wires on a substrate, coating an insulating layer on the circuit board; removing the insulating layer upon the wires so as to expose the wires; and then performing PTH process and plating copper for forming another wires. Thereby, line thickness of the printed circuit board is increased and the wires are stacked continuously.

The various objects and advantages of the present invention will be more readily understood from the following detailed description when read in conjunction with the appended drawing.

### BRIEF DESCRIPTION OF THE DRAWINGS

FIG. 1 is a cross sectional view illustrating the substrate with copper foil.

FIG. 2 shows a first cross sectional view illustrating the method for manufacturing a printed circuit board according to the present invention.

FIG. 3 shows a second cross sectional view illustrating the method for manufacturing a printed circuit board according to the present invention.

FIG. 4 shows a third cross sectional view illustrating the method for manufacturing a printed circuit board according to the present invention.

FIG. 5 shows a fourth cross sectional view illustrating the method for manufacturing a printed circuit board according to the present invention.

FIG. 6 shows a fifth cross sectional view illustrating the method for manufacturing a printed circuit board according to the present invention.

FIG. 7 is a schematic view showing stacking wires on a printed circuit board according to the present invention.

FIG. 8 is a schematic view showing that the wires are stacking as a rectangular shape according to the present invention.

### DETAILED DESCRIPTION OF THE PREFERRED EMBODIMENTS

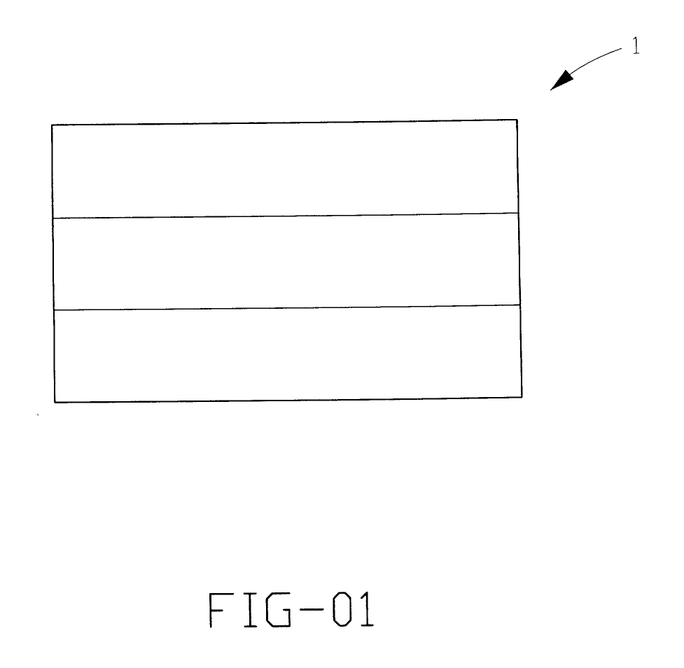

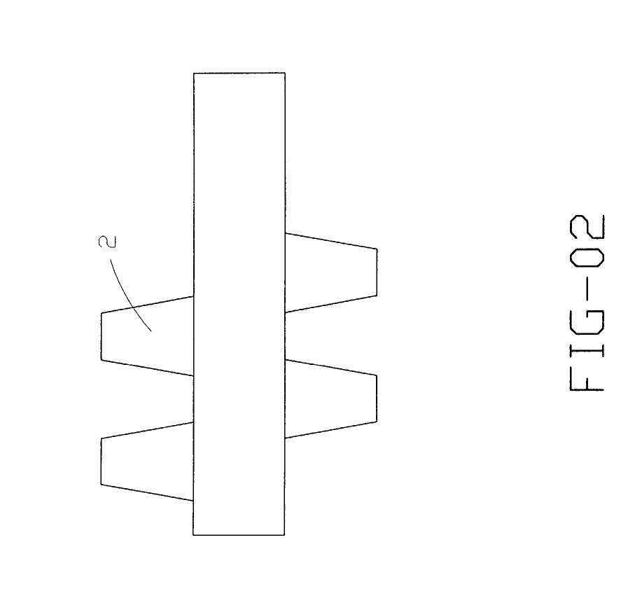

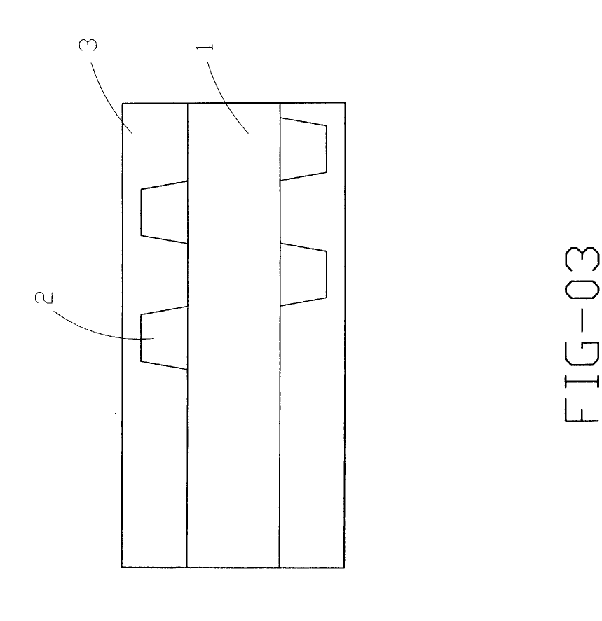

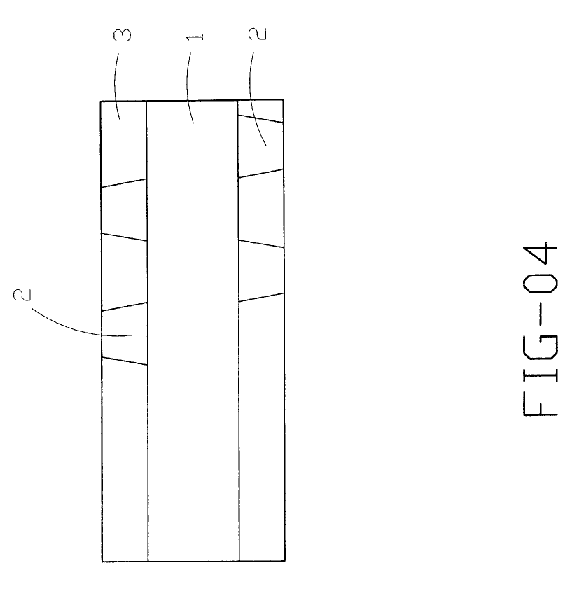

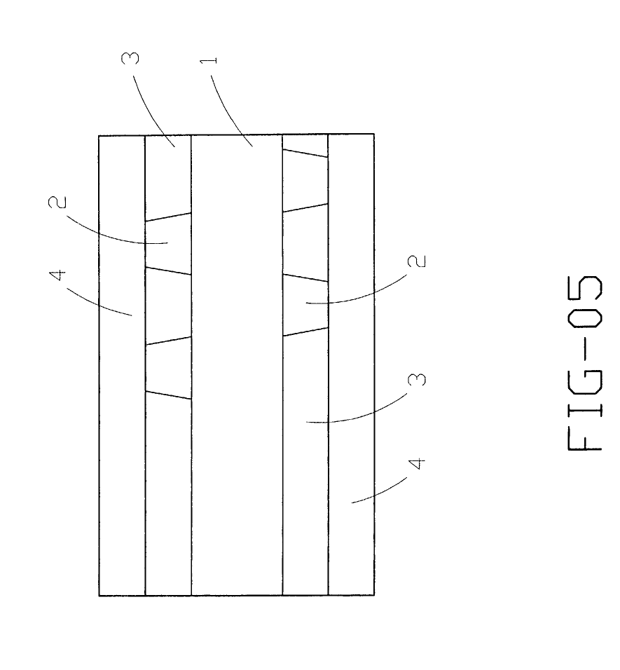

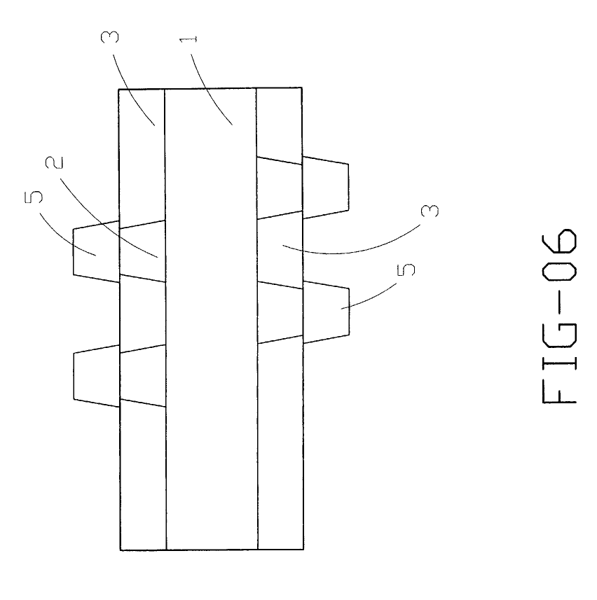

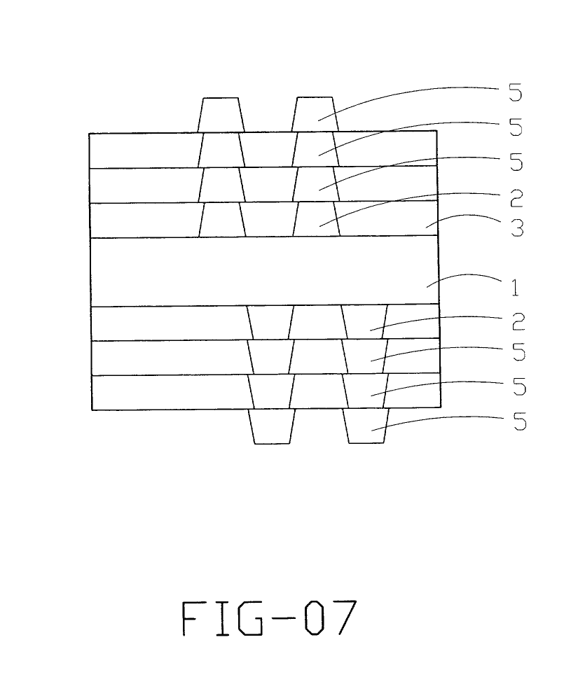

Referring to FIGS. 1, the method for manufacturing a printed circuit board (PCB) based on the present invention comprises the following steps. Wires are formed on a substrate 1 by pretreatment, coating or laminating photoimageable resist; exposing, developing, and etching to form circuit 2 (referring to FIG. 2). Then, an insulating layer is coated on the circuit board. The insulating layer 3 upon the wires 2 is removed so as to expose the wires, as shown in FIGS. 3 and 4. Then PTH process and plating copper are performed for forming another wires 4, as illustrated in FIG. 5. Above processes are repeated; thereby, multiple-layers of wires being formed, see FIG. 6. Referring to FIG. 7, if the thickness is enough, finally the circuit board is drilled and the conventional PCB process is executed to make a finished good PCB.

In the following, a circuit of 4OZ thickness with 5 mil line width is used as an example.

For a circuit with thickness/Width ratio to be 5.6/5=1.1, a reference manufacturing process is as the following steps:

1. Cut a substrate of 2OZ copper foil to a desired panel size and drill positioning holes or position the circuit board by other ways.

2. Wires are formed on a substrate by pretreatment, coating or laminating photoimageable resist, exposing, developing, and etching.

3. Coat an insulating layer on the substrate. The material of the insulating layer is selected from one of a solder resist and epoxy resin and other materials same as the substrate.

4. level and then remove the insulating layer upon the wires (by for example, exposing and developing, mechanical or chemical ways).

5. Perform PTH and plate Copper to IOZ.

6. Repeat the steps 2 to 5 for continuously stacking wires to increase the thickness of the circuit if the thickness requirement is more than 40Z.

7. Drill holes

8. Perform PTH and plate Copper again. If a negative process is used, copper is plated thereon to a thickness of 0.2 to 0.3 mils, and if a positive process is used, copper is plateed to a thickness of 1.4 mil.

9. Perform other conventional PCB manufacturing process to complete a printed circuit board.

It is apparent that the present invention has the following features.

1. The thickness of the circuit can be stacked to a desired value (be repeating the reference manufacturing process 2 to 5).

2. The stacking process can be used to the inner and outer layers of the printed circuit board by performing the steps 2 to 5.

3. The conductor area for same wires width can be increased so that the current carried by each wire is increased.

4. The line width can be reduced. That is, the width and thickness of the wires are adjustable.

5. Insulating material is filled between wires so as to increase the reliability is incremented and a preferred insulating effect is achieved.

6. The solder resist is easy printed because insulating materials are filled between conductor already and legend can be printed thereon clearly and completely.

7. The shape for stacking wire is changeable based on the manufacturing process, for example, rectangular shape, oblong shape, trapezoidal shape, rever trapezodial shape, etc.

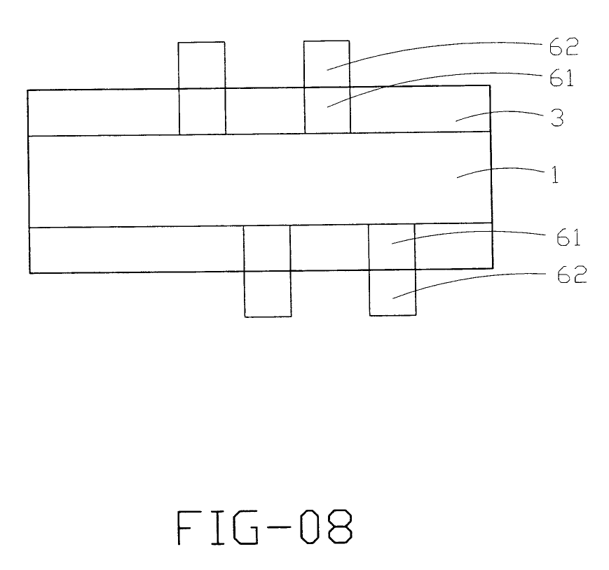

FIG. 7 shows another embodiment of manufacturing a circuit board according to the present invention. It is illustrated that wires 5, 5, 5, are continuously stacked. FIG. 8 is an embodiment, wherein the wire 61 and a continuous stacking wires 62 are realized by a rectangular shape.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A method for manufacturing a printed circuit board comprising the steps of:
forming wires on a substrate by pretreatment, coating or laminating photoimageable resist, exposing, developing, etching;
coating an insulating layer on the circuit board;
removing the insulating layer upon the wires so as to expose the wires;
performing PTH process and plating copper for forming another wires;
repeated above process; thereby, multiple-stacked layers of wires being formed; and
drilling holes.

2. The method for manufacturing a printed circuit board as claimed in claim 1, wherein materials identical to the substrate are used as materials of insulating layer.

3. The method for manufacturing a printed circuit board as claimed in claim 1, wherein the insulating layer is selected from one of a solder resist materials and epoxy resin.

4. The method for manufacturing a printed circuit board as claimed in claim 1, wherein the step of removing the insulating layer upon the wires so as to expose the wires is performed by a way selected from one of a group containing performing photoimageable solder resist process exposing and developing ways, mechanical ways and chemical ways.

5. The method for manufacturing a printed circuit board as claimed in claim 1, wherein the method is used to form an internal circuit of the printed circuit board.

6. The method for manufacturing a printed circuit board as claimed in claim 1, wherein the method is used to form an external circuit of the printed circuit board.

7. The method for manufacturing a printed circuit board as claimed in claim 1, wherein in the printed circuit board, the width of the wire is reduced and the thickness is increased.

8. A printed circuit board with stacking wires comprising a plurality of wire layers, each wire layers being formed by pretreatment, coating or laminating photoimageable resist, developing, etching wires upon a substrate; coating an insulating layer on the circuit board; removing the insulating layer on the wires so as to expose the wires; and then performing PTH process and plating copper for forming another wires; thereby, line thickness of the printed circuit board being increased and the wires being stacked continuously.

9. The printed circuit board as claimed in claim 8, wherein the staked wires are an interior circuit of a printed circuit board.

10. The a printed circuit board as claimed in claim 8, wherein the staked wires are an outer circuit of a printed circuit board.

11. A printed circuit board with stacking wires of various shapes comprising a plurality of wire layers each having a predetermined shape, each wire layers being formed by pretreatment, coating or laminating photoimageable resist, developing, etching wires upon a substrate; coating an insulating layer on the circuit board; removing the insulating layer on the wires so as to expose the wires; and then performing PTH process and plating copper for forming another wires; thereby, line thickness of the printed circuit board being increased and the wires being stacked continuously.
